(19) United States
(12) Patent Application Publication
(10) Pub. No.: US 2025/0351498 A1
(43) Pub. Date: Nov. 13, 2025

(54) SEMICONDUCTOR DEVICE

(71) Applicant: FUJI ELECTRIC CO., LTD., Kanagawa (JP)

(72) Inventors: Hidenori TSUJI, Higashimurayama-city (JP); Takashi YOSHIMURA, Matsumoto-city (JP); Shuntaro YAGUCHI, Matsumoto-city (JP); Shinya TAKASHIMA, Hachioji-city (JP); Katsunori UENO, Matsumoto-city (JP)

(21) Appl. No.: 19/277,316

(22) Filed: Jul. 22, 2025

Related U.S. Application Data
(63) Continuation of application No. PCT/JP2024/027384, filed on Jul. 31, 2024.

(30) Foreign Application Priority Data
Aug. 1, 2023 (JP) 2023-125870

(51) Int. Cl. H10D 62/60; H10D 8/00; H10D 12/00; H10D 62/10; H10D 84/00

(52) U.S. Cl. CPC H10D 62/60; H10D 8/422; H10D 12/481; H10D 62/103; H10D 84/161

(57) ABSTRACT

Provided is a semiconductor device including: a first doping concentration peak farthest from a lower surface of a semiconductor substrate; and a second doping concentration peak second farthest from the lower surface, in which a predetermined conditional expression is satisfied when an integrated concentration of Si—H donors at the first doping concentration peak is denoted as N₁, an integrated concentration of CiOi-H donors between the first doping concentration peak and the second doping concentration peak is denoted as N_{COH}, a carbon chemical concentration of the semiconductor substrate is denoted as N_{C}, and N=N₁+N_{COH}.

The contents of the following patent application (s) are incorporated herein by reference:
NO. 2023-125870 filed in JP on Aug. 1, 2023
NO. PCT/JP2024/027384 filed in WO on Jul. 31, 2024.

### BACKGROUND

### 1. Technical Field

The present invention relates to a semiconductor device.

### 2. Related Art

A technique to form a semiconductor device, such as a transistor, on a semiconductor substrate is known (for example, see Patent Document 1 and 2).

### RELATED ART DOCUMENTS

### Patent Document

Patent Document 1: International Publication No. WO2016/204227
Patent Document 2: Japanese Patent Application Publication No. 2022-062443

### BRIEF DESCRIPTION OF THE DRAWINGS

FIG. 1 is a top plan view showing an example of a semiconductor device 100 according to one embodiment of the present invention.

FIG. 2 shows an enlarged view of a region D in FIG. 1.

FIG. 3 is a view showing an example of a cross section e-e in FIG. 2.

FIG. 4 is a diagram showing an example of a distribution 220 of a hydrogen chemical concentration and a distribution 210 of a doping concentration in line f-f of FIG. 3.

FIG. 5 is a diagram explaining a method for estimating concentrations of an interstitial Si—H donor and a CiOi-H donor.

FIG. 6 is a diagram showing results of measuring a ratio of the CiOi-H donor.

FIG. 7 is a diagram showing a variation Nₘₐₓ/Nₘᵢₙ of an integrated value N of a hydrogen donor concentration under each implantation condition.

FIG. 8 is a diagram showing a relationship between the CiOi-H donor ratio and the variation Nₘₐₓ/Nₘᵢₙ of the integrated value N of the hydrogen donor concentration.

FIG. 9 is a diagram showing the relationship between the CiOi-H donor ratio and the variation Nₘₐₓ/Nₘᵢₙ of the integrated value N of the hydrogen donor concentration.

FIG. 10 is a diagram in which the CiOi-H donor ratio at each carbon chemical concentration is plotted by a hexagonal mark when the variation Nₘₐₓ/Nₘᵢₙ is set to 1.3.

FIG. 11 is a diagram showing a boundary line corresponding to a condition for setting the variation Nₘₐₓ/Nₘᵢₙ to 1.7 or less, 1.5 or less, or 1.3 or less.

FIG. 12 is a diagram showing a curve obtained by fitting the CiOi-H donor ratio with a common logarithm of a carbon concentration for each condition of Implantation Conditions 1 to 7.

FIG. 13 is a diagram in which the CiOi-H donor ratio is plotted with a substrate concentration index Ic as a horizontal axis for each condition of Implantation Conditions 1 to 7.

FIG. 14 is a diagram showing an example of a doping concentration distribution of a buffer region 20 according to one embodiment of the present invention.

FIG. 15 is a diagram showing an example of a doping concentration distribution of a buffer region 20 according to a reference example.

### DESCRIPTION OF EXEMPLARY EMBODIMENTS

Hereinafter, the present invention will be described through embodiments of the invention, but the following embodiments do not limit the invention according to claims. In addition, not all combinations of features described in the embodiments are essential to a solution of the invention.

As used herein, one side in a direction parallel to a depth direction of a semiconductor substrate is referred to as an “upper” side and another side is referred to as a “lower” side. One surface of two principal surfaces of a substrate, a layer, or another member is referred to as an upper surface, and another surface is referred to as a lower surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate a height direction with respect to the ground. It should be noted that a +Z axis direction and a −Z axis direction are directions opposite to each other. If a Z axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. In the present specification, the direction of the Z axis may be referred to as a depth direction. In addition, in the present specification, a direction parallel to the upper surface and the lower surface of the semiconductor substrate may be referred to as a horizontal direction, including an X axis direction and a Y axis direction.

A region from the center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type or a semiconductor presenting a conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}-N_{A}. In the present specification, the net doping concentration may be simply referred to as the doping concentration.

The donor has a function of supplying electrons to a semiconductor. The acceptor has a function of receiving electrons from the semiconductor. The donor and the acceptor are not limited to the impurities themselves. For example, interstitial Si—H in which interstitial silicon (Si-i) in a silicon semiconductor is attached to hydrogen, and CiOi-H in which interstitial carbon (Ci) is attached to interstitial oxygen (Oi) and hydrogen also function as the donor which supplies electrons. In the present specification, the CiOi-H, or the interstitial Si—H may be referred to as a hydrogen donor.

In the semiconductor substrate in the present specification, bulk donors of the N type are distributed throughout. The bulk donor is a dopant donor substantially uniformly contained in an ingot during manufacturing of the ingot from which the semiconductor substrate is made. The bulk donor in the present example is an element other than hydrogen. A dopant of the bulk donor is, for example, phosphorous, antimony, arsenic, selenium, or sulfur, but is not limited to these. The bulk donor in the present example is phosphorous. The bulk donor is also contained in a region of the P type. The semiconductor substrate may be a wafer cut out from a semiconductor ingot, or may be a chip obtained by singulating the wafer. The semiconductor ingot may be manufactured by any one of a Czochralski method (CZ method), a magnetic field applied Czochralski method (MCZ method), or a float zone method (FZ method). The ingot in the present example is manufactured by the MCZ method. The substrate manufactured by the MCZ method has an oxygen concentration of 1×10¹⁷ to 7×10¹⁷/cm³. The substrate manufactured by the FZ method has an oxygen concentration of 1×10¹⁵ to 5×10¹⁶/cm³. When the oxygen concentration is high, the hydrogen donor tends to be easily generated. A bulk donor concentration may use a chemical concentration of the bulk donors distributed throughout the semiconductor substrate, or may be a value between 90% and 100% of the chemical concentration. In addition, as the semiconductor substrate, a non-doped substrate not containing a dopant such as phosphorous may be used. In that case, a bulk donor concentration (DO) of the non-doped substrate is, for example, from 1×10¹⁰/cm³ or more and to 5×10¹²/cm³ or less. The bulk donor concentration (DO) of the non-doped substrate is preferably 1×10¹¹/cm³ or more. The bulk donor concentration (DO) of the non-doped substrate is preferably 5×10¹²/cm³ or less. Note that each concentration in the present invention may be a value at room temperature. As an example, a value at 300K (Kelvin) (about 26.9 degrees C.) may be used as the value at room temperature.

In the present specification, a description of a P+ type or an N+ type means a higher doping concentration than that of the P type or the N type, and a description of a P− type or an N− type means a lower doping concentration than that of the P type or the N type. In addition, in the present specification, a description of a P++ type or an N++ type means a higher doping concentration than that of the P+ type or the N+ type. In the present specification, a unit system is an SI unit system unless otherwise noted. Although a unit of a length may be expressed in cm, various calculations may be performed after conversion to meters (m).

A chemical concentration in the present specification refers to an atomic density of an impurity measured regardless of an electrical activation state. The chemical concentration can be measured by, for example, secondary ion mass spectrometry (SIMS). The net doping concentration described above can be measured by capacitance—voltage profiling (CV profiling). In addition, a carrier concentration measured by spreading resistance profiling (SRP method) may be set as the net doping concentration. The carrier concentration measured by the CV profiling or the SRP method may be a value in a thermal equilibrium state. In addition, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

When a concentration distribution of the donor, acceptor, or net doping has a peak in a region, a value of the peak may be defined as the concentration of the donor, acceptor, or net doping in the region. In a case where the concentration of the donor, acceptor or net doping is substantially uniform in a region, or the like, an average donor, acceptor or net doping concentration in the region may be defined as a donor, acceptor or net doping concentration. In the present specification, atoms/cm³ or/cm³ is used to express a concentration per unit volume. This unit is used for the donor or acceptor concentration or the chemical concentration in the semiconductor substrate. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The reduction in the carrier mobility occurs when carriers are scattered due to disorder (disorder) of a crystal structure due to a lattice defect or the like.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorous or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen.

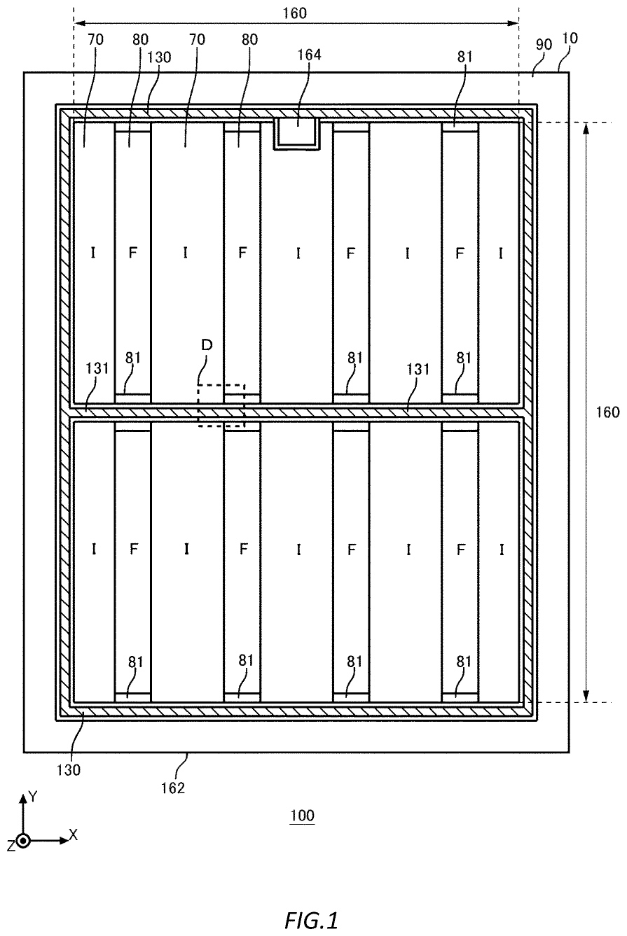

FIG. 1 is a top plan view showing an example of a semiconductor device 100 according to one embodiment of the present invention. FIG. 1 shows a position of each member projected onto an upper surface of a semiconductor substrate 10. In FIG. 1, only some members of the semiconductor device 100 are shown, and illustrations of some members are omitted.

The semiconductor device 100 includes the semiconductor substrate 10. The semiconductor substrate 10 is a substrate which is formed of a semiconductor material. As an example, the semiconductor substrate 10 is a silicon substrate. The semiconductor substrate 10 has an end side 162 in a top view. When simply referred to as the top view in the present specification, it means that the semiconductor substrate 10 is viewed from an upper surface side. The semiconductor substrate 10 in the present example has two sets of end sides 162 opposite to each other in the top view. In FIG. 1, the X axis and the Y axis are parallel to any of the end sides 162. In addition, the Z axis is perpendicular to the upper surface of the semiconductor substrate 10.

The semiconductor substrate 10 is provided with an active portion 160. The active portion 160 is a region where a main current flows in a depth direction between the upper surface and a lower surface of the semiconductor substrate 10 when the semiconductor device 100 operates. An emitter electrode is provided above the active portion 160, but illustration thereof is omitted in FIG. 1. The active portion 160 may refer to a region which overlaps with the emitter electrode in the top view. In addition, a region sandwiched between active portions 160 in the top view may also be included in the active portion 160.

The active portion 160 is provided with at least one of a transistor portion 70 including a transistor element such as an insulated gate bipolar transistor (IGBT) or a diode portion 80 including a diode element such as a freewheeling diode (FWD). In the example shown in FIG. 1, transistor portions 70 and diode portions 80 are alternately arranged along a predetermined array direction (the X axis direction in the present example) at the upper surface of the semiconductor substrate 10. The semiconductor device 100 in the present example is a reverse conduction type IGBT (RC-IGBT).

In FIG. 1, a region where each of the transistor portions 70 is arranged is indicated by a symbol “I”, and a region where each of the diode portions 80 is arranged is indicated by a symbol “F”. In the present specification, a direction perpendicular to the array direction in the top view may be referred to as an extending direction (the Y axis direction in FIG. 1). Each of the transistor portions 70 and the diode portions 80 may have a longitudinal length in the extending direction. In other words, a length of the transistor portion 70 in the Y axis direction is greater than a width in the X axis direction. Similarly, a length of the diode portion 80 in the Y axis direction is greater than a width in the X axis direction. The extending directions of the transistor portion 70 and the diode portion 80, and a longitudinal direction of each trench portion described below may be the same.

Each of the diode portions 80 includes a cathode region of the N+ type in a region in contact with the lower surface of the semiconductor substrate 10. In the present specification, a region where the cathode region is provided is referred to as the diode portion 80. In other words, the diode portion 80 is a region which overlaps with the cathode region in the top view. At the lower surface of the semiconductor substrate 10, a collector region of the P+ type may be provided in a region other than the cathode region. In the present specification, the diode portion 80 may also include an extension region 81 where the diode portion 80 extends to a gate runner described below in the Y axis direction. The collector region is provided at a lower surface of the extension region 81.

The transistor portion 70 has the collector region of the P+ type in a region in contact with the lower surface of the semiconductor substrate 10. In addition, in the transistor portion 70, an emitter region of the N type, a base region of the P type, and a gate structure having a gate conductive portion and a gate dielectric film are periodically arranged at the upper surface side of the semiconductor substrate 10.

The semiconductor device 100 may have one or more pads above the semiconductor substrate 10. The semiconductor device 100 in the present example has a gate pad 164. The semiconductor device 100 may have a pad such as an anode pad, a cathode pad, and a current detection pad. Each pad is arranged in a vicinity of the end side 162. The vicinity of the end side 162 refers to a region between the end side 162 and the emitter electrode in the top view. When the semiconductor device 100 is mounted, each pad may be connected to an external circuit via a wiring such as a wire.

A gate potential is applied to the gate pad 164. The gate pad 164 is electrically connected to a conductive portion of a gate trench portion of the active portion 160. The semiconductor device 100 includes the gate runner that connects the gate pad 164 to the gate trench portion. In FIG. 1, the gate runner is hatched with diagonal lines.

The gate runner in the present example has an outer circumferential gate runner 130 and an active side gate runner 131. The outer circumferential gate runner 130 is arranged between the active portion 160 and the end side 162 of the semiconductor substrate 10 in the top view. The outer circumferential gate runner 130 in the present example encloses the active portion 160 in the top view. A region enclosed by the outer circumferential gate runner 130 in the top view may be set as the active portion 160. In addition, a well region is formed below the gate runner. The well region is a P type region having a higher concentration than that of the base region described below, and is formed from the upper surface of the semiconductor substrate 10 to a position deeper than that of the base region. A region enclosed by the well region in the top view may be set as the active portion 160.

The outer circumferential gate runner 130 is connected to the gate pad 164. The outer circumferential gate runner 130 is arranged above the semiconductor substrate 10. The outer circumferential gate runner 130 may be a metal wiring containing aluminum or the like.

The active side gate runner 131 is provided in the active portion 160. Providing the active side gate runner 131 in the active portion 160 can reduce a variation in a wiring length from the gate pad 164 for each region of the semiconductor substrate 10.

The outer circumferential gate runner 130 and the active side gate runner 131 are connected to the gate trench portion of the active portion 160. The outer circumferential gate runner 130 and the active side gate runner 131 are arranged above the semiconductor substrate 10. The outer circumferential gate runner 130 and the active side gate runner 131 may be a wiring formed of a semiconductor such as polysilicon doped with an impurity.

The active side gate runner 131 may be connected to the outer circumferential gate runner 130. The active side gate runner 131 in the present example is provided to extend in the X axis direction so as to cross the active portion 160 substantially at the center of the Y axis direction from one outer circumferential gate runner 130 to another outer circumferential gate runner 130 which sandwich the active portion 160. When the active portion 160 is divided by the active side gate runner 131, the transistor portions 70 and the diode portions 80 may be alternately arranged in the X axis direction in each divided region.

The semiconductor device 100 may include a temperature sensing portion (not shown) that is a PN junction diode formed of polysilicon or the like, and a current detection portion (not shown) that simulates an operation of the transistor portion provided in the active portion 160.

The semiconductor device 100 in the present example includes an edge termination structure portion 90 between the active portion 160 and the end side 162 in the top view. The edge termination structure portion 90 in the present example is arranged between the outer circumferential gate runner 130 and the end side 162. The edge termination structure portion 90 reduces an electric field strength on the upper surface side of the semiconductor substrate 10. The edge termination structure portion 90 may include at least one of a guard ring, a field plate, or a RESURF which are annularly provided to enclose the active portion 160.

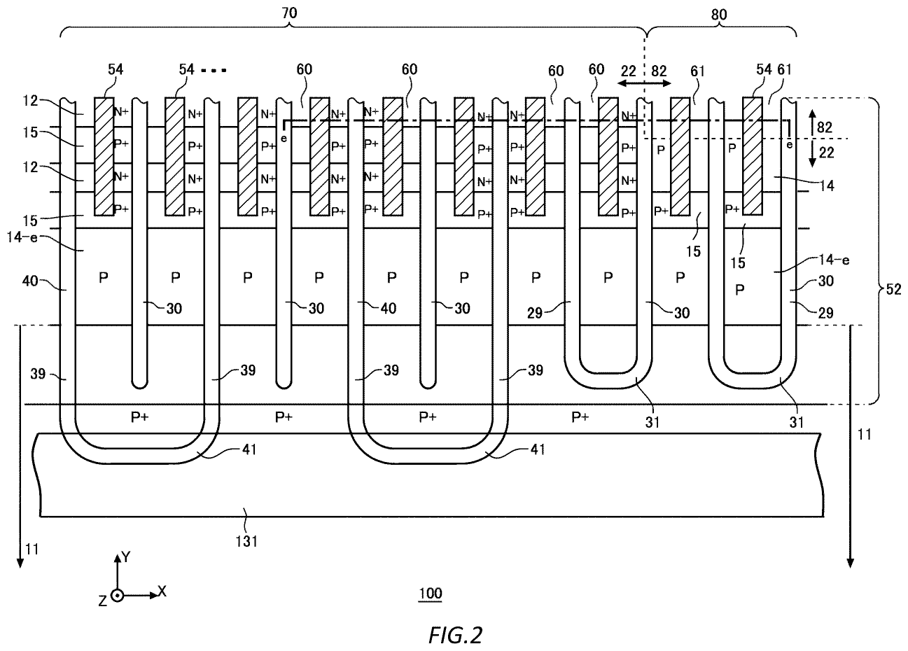

FIG. 2 shows an enlarged view of a region D in FIG. 1. The region D is a region including a transistor portion 70, a diode portion 80, and the active side gate runner 131. The semiconductor device 100 in the present example includes a gate trench portion 40, a dummy trench portion 30, a well region 11, an emitter region 12, a base region 14, and a contact region 15 which are provided inside the upper surface side of the semiconductor substrate 10. Each of the gate trench portion 40 and the dummy trench portions 30 is an example of the trench portion. In addition, the semiconductor device 100 in the present example includes an emitter electrode 52 and the active side gate runner 131 which are provided above the upper surface of the semiconductor substrate 10. The emitter electrode 52 and the active side gate runner 131 are provided to be separate from each other.

An interlayer dielectric film is provided between the emitter electrode 52 and the active side gate runner 131, and the upper surface of the semiconductor substrate 10; however, the interlayer dielectric film is omitted in FIG. 2. In the interlayer dielectric film in the present example, a contact hole 54 is provided to pass through the interlayer dielectric film. In FIG. 2, each contact hole 54 is hatched with diagonal lines.

The emitter electrode 52 is provided above the gate trench portion 40, the dummy trench portion 30, the well region 11, the emitter region 12, the base region 14, and the contact region 15. The emitter electrode 52 is in contact with the emitter region 12, the contact region 15, and the base region 14 at the upper surface of the semiconductor substrate 10, through the contact hole 54. In addition, the emitter electrode 52 is connected to a dummy conductive portion in the dummy trench portion 30 through the contact hole provided in the interlayer dielectric film. The emitter electrode 52 may be connected to the dummy conductive portion of the dummy trench portion 30 at an edge of the dummy trench portion 30 in the Y axis direction. The dummy conductive portion of the dummy trench portion 30 may not be connected to the emitter electrode 52 and a gate conductive portion, and may be controlled to be at a potential different from a potential of the emitter electrode 52 and a potential of the gate conductive portion.

The active side gate runner 131 is connected to the gate trench portion 40 through the contact hole provided in the interlayer dielectric film. The active side gate runner 131 may be connected to a gate conductive portion of the gate trench portion 40 at an edge portion 41 of the gate trench portion 40 in the Y axis direction. The active side gate runner 131 is not connected to the dummy conductive portion in the dummy trench portion 30.

The emitter electrode 52 is formed of a material containing metal. FIG. 2 shows a range where the emitter electrode 52 is provided. For example, at least a partial region of the emitter electrode 52 is formed of aluminum or an aluminum-silicon alloy, for example, a metal alloy such as AlSi or AlSiCu. The emitter electrode 52 may have a barrier metal formed of titanium, a titanium compound, or the like below a region formed of aluminum or the like. Further, a plug, which is formed by embedding tungsten or the like so as to be in contact with the barrier metal and aluminum or the like, may be included in the contact hole.

The well region 11 is provided to overlap with the active side gate runner 131. The well region 11 is provided to extend with a predetermined width even in a range that does not overlap with the active side gate runner 131. The well region 11 in the present example is provided to be spaced apart from an end of the contact hole 54 in the Y axis direction toward the active side gate runner 131. The well region 11 is a region of a second conductivity type having a higher doping concentration than that of the base region 14. The base region 14 in the present example is of the P− type, and the well region 11 is of the P+ type.

Each of the transistor portion 70 and the diode portion 80 has a plurality of trench portions arrayed in an array direction. In the transistor portion 70 in the present example, one or more gate trench portions 40 and one or more dummy trench portions 30 are alternately provided along the array direction. In the diode portion 80 in the present example, a plurality of dummy trench portions 30 are provided along the array direction. In the diode portion 80 in the present example, the gate trench portion 40 is not provided.

The gate trench portion 40 in the present example may have two linear portions 39 extending along the extending direction perpendicular to the array direction (parts of a trench which are linear along the extending direction), and the edge portion 41 connecting the two linear portions 39. The extending direction in FIG. 2 is the Y axis direction.

At least a part of the edge portion 41 is preferably provided in a curved shape in the top view. By connecting between end portions of the two linear portions 39 in the Y axis direction by the edge portion 41, it is possible to reduce the electric field strength at the end portions of the linear portions 39.

In the transistor portion 70, the dummy trench portions 30 are provided between the respective linear portions 39 of the gate trench portions 40. Between the respective linear portions 39, one dummy trench portion 30 may be provided, or the plurality of dummy trench portions 30 may be provided. The dummy trench portion 30 may have a linear shape extending in the extending direction, or may have linear portions 29 and an edge portion 31 similarly to the gate trench portion 40. The semiconductor device 100 shown in FIG. 2 includes both of the linear dummy trench portion 30 having no edge portion 31, and the dummy trench portion 30 having the edge portion 31.

A diffusion depth of the well region 11 may be deeper than depths of the gate trench portion 40 and the dummy trench portion 30. The end portions in the Y axis direction of the gate trench portion 40 and the dummy trench portion 30 are provided in the well region 11 in the top view. In other words, at the end portion of each trench portion in the Y axis direction, a bottom portion of each trench portion in the depth direction is covered with the well region 11. With this configuration, the electric field strength at the bottom portion of each trench portion can be reduced.

A mesa portion is provided between the respective trench portions in the array direction. The mesa portion refers to a region sandwiched between the trench portions inside the semiconductor substrate 10. As an example, an upper end of the mesa portion is the upper surface of the semiconductor substrate 10. A depth position of a lower end of the mesa portion is the same as a depth position of a lower end of the trench portion. The mesa portion in the present example is provided to extend in the extending direction (the Y axis direction) along the trench, at the upper surface of the semiconductor substrate 10. In the present example, a mesa portion 60 is provided in the transistor portion 70, and a mesa portion 61 is provided in the diode portion 80. As merely referred to as the mesa portion in the present specification, it indicates each of the mesa portion 60 and the mesa portion 61.

Each mesa portion is provided with the base region 14. In the mesa portion, a region arranged to be closest to the active side gate runner 131, in the base region 14 exposed to the upper surface of the semiconductor substrate 10, is set as a base region 14-e. While FIG. 2 shows the base region 14-e arranged at one end portion of each mesa portion in the extending direction, the base region 14-e is also arranged at another end portion of each mesa portion. Each mesa portion may be provided with at least one of the emitter region 12 of a first conductivity type, or the contact region 15 of the second conductivity type in a region sandwiched between the base regions 14-e in the top view. In the present example, the emitter region 12 is of the N+ type, and the contact region 15 is the P+ type. The emitter region 12 and the contact region 15 may be provided between the base region 14 and the upper surface of the semiconductor substrate 10 in the depth direction.

The mesa portion 60 of the transistor portion 70 has the emitter region 12 exposed to the upper surface of the semiconductor substrate 10. The emitter region 12 is provided in contact with the gate trench portion 40. The mesa portion 60 in contact with the gate trench portion 40 may be provided with the contact region 15 exposed on the upper surface of the semiconductor substrate 10.

Each of the contact region 15 and the emitter region 12 in the mesa portion 60 is provided from one trench portion to another trench portion in the X axis direction. As an example, the contact regions 15 and the emitter regions 12 of the mesa portion 60 are alternately arranged along the extending direction of the trench portion (the Y axis direction).

In another example, the contact region 15 and the emitter region 12 of the mesa portion 60 may be provided in a stripe shape along the extending direction of the trench portion (the Y axis direction). For example, the emitter region 12 is provided in a region in contact with the trench portion, and the contact region 15 is provided in a region sandwiched between the emitter regions 12.

The mesa portion 61 of the diode portion 80 is not provided with the emitter region 12. The base regions 14 and the contact regions 15 may be provided at an upper surface of the mesa portion 61. In the region sandwiched between the base regions 14-e at the upper surface of the mesa portion 61, the contact region 15 may be provided in contact with each of the base regions 14-e. The base region 14 may be provided in a region sandwiched between the contact regions 15 at the upper surface of the mesa portion 61. The base region 14 may be arranged in the entire region sandwiched between the contact regions 15.

The contact hole 54 is provided above each mesa portion. The contact hole 54 is arranged in the region sandwiched between the base regions 14-e. The contact hole 54 in the present example is provided above each region of the contact region 15, the base region 14, and the emitter region 12. The contact hole 54 is not provided in regions corresponding to the base region 14-e and the well region 11. The contact hole 54 may be arranged at a center of the mesa portion 60 in the array direction (the X axis direction).

In the diode portion 80, a cathode region 82 of the N+ type is provided in a region adjacent to the lower surface of the semiconductor substrate 10. At the lower surface of the semiconductor substrate 10, the collector region 22 of the P+ type may be provided in a region where the cathode region 82 is not provided. The cathode region 82 and the collector region 22 are provided between a lower surface 23 of the semiconductor substrate 10 and a buffer region 20. In FIG. 2, a boundary between the cathode region 82 and the collector region 22 is indicated by a dotted line.

The cathode region 82 is arranged to be spaced apart from the well region 11 in the Y axis direction. With this configuration, the distance between a region of the P type (the well region 11) having a relatively high doping concentration and formed up to the deep position, and the cathode region 82 is ensured, so that a breakdown voltage can be improved. An end portion of the cathode region 82 in the Y axis direction in the present example is arranged to be spaced apart from the well region 11 farther than an end portion of the contact hole 54 in the Y axis direction. In another example, the end portion of the cathode region 82 in the Y axis direction may be arranged between the well region 11 and the contact hole 54.

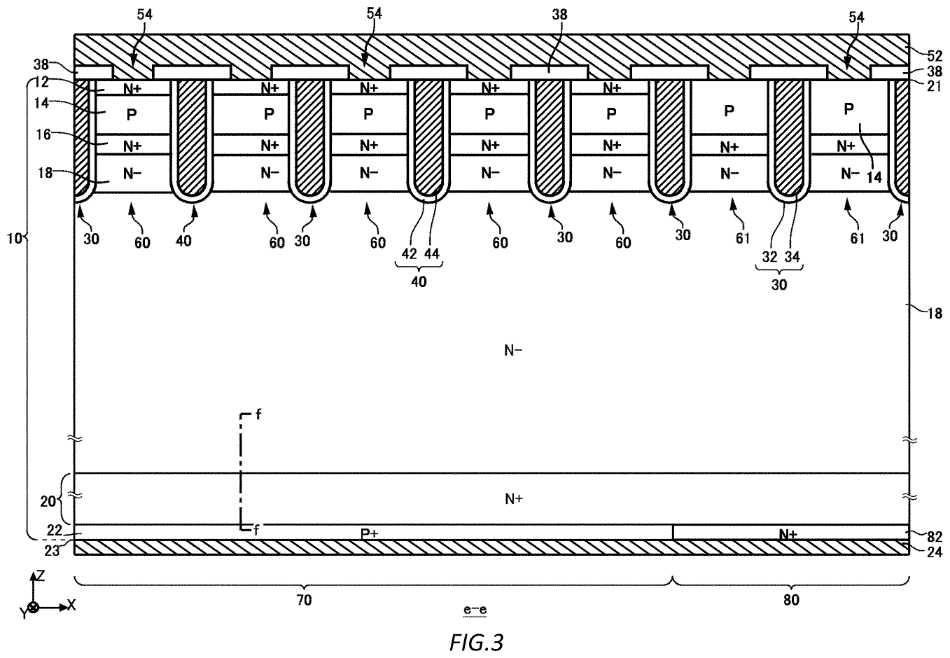

FIG. 3 is a view showing an example of a cross section e-e in FIG. 2. The cross section e-e is an XZ plane passing through the emitter region 12 and the cathode region 82. The semiconductor device 100 in the present example includes the semiconductor substrate 10, an interlayer dielectric film 38, the emitter electrode 52, and a collector electrode 24 in the cross section.

The interlayer dielectric film 38 is provided on the upper surface of the semiconductor substrate 10. The interlayer dielectric film 38 is a film including at least one layer of a dielectric film such as silicate glass to which an impurity such as boron or phosphorous is added, a thermal oxide film, or other dielectric films. The interlayer dielectric film 38 is provided with the contact hole 54 described with reference to FIG. 2.

The emitter electrode 52 is provided above the interlayer dielectric film 38. The emitter electrode 52 is in contact with the upper surface 21 of the semiconductor substrate 10 through the contact hole 54 of the interlayer dielectric film 38. The collector electrode 24 is provided at the lower surface 23 of the semiconductor substrate 10. The emitter electrode 52 and the collector electrode 24 are formed of a metal material such as aluminum. In the present specification, a direction (the Z axis direction) in which the emitter electrode 52 is connected to the collector electrode 24 is referred to as the depth direction.

The semiconductor substrate 10 includes a drift region 18 of the N type or the N− type. The drift region 18 is provided in each of the transistor portion 70 and the diode portion 80.

In the mesa portion 60 of the transistor portion 70, the emitter region 12 of the N+ type and the base region 14 of the P− type are provided in order starting from an upper surface 21 side of the semiconductor substrate 10. The drift region 18 is provided below the base region 14. The mesa portion 60 may be provided with an accumulation region 16 of the N+ type. The accumulation region 16 is arranged between the base region 14 and the drift region 18.

The emitter region 12 is exposed to the upper surface 21 of the semiconductor substrate 10 and is provided in contact with the gate trench portion 40. The emitter region 12 may be in contact with the trench portions on both sides of the mesa portion 60. The emitter region 12 has a higher doping concentration than that of the drift region 18.

The base region 14 is provided below the emitter region 12. The base region 14 in the present example is provided in contact with the emitter region 12. The base region 14 may be in contact with the trench portions on both sides of the mesa portion 60.

The accumulation region 16 is provided below the base region 14. The accumulation region 16 is a region of the N+ type having a higher doping concentration than that of the drift region 18. That is, the accumulation region 16 has a higher donor concentration than that of the drift region 18. Providing the accumulation region 16 having a high concentration between the drift region 18 and the base region 14 can increase a carrier injection enhancement effect (IE effect) and reduce an on-voltage. The accumulation region 16 may be provided so as to cover an entire lower surface of the base region 14 in each mesa portion 60.

In the mesa portion 61 of the diode portion 80, the base region 14 of the P− type is provided in contact with the upper surface 21 of the semiconductor substrate 10. The drift region 18 is provided below the base region 14. In the mesa portion 61, the accumulation region 16 may be provided below the base region 14.

In each of the transistor portion 70 and the diode portion 80, the buffer region 20 of the N+ type may be provided below the drift region 18. A doping concentration of the buffer region 20 is higher than the doping concentration of the drift region 18. The buffer region 20 may have a concentration peak having a higher doping concentration than that of the drift region 18. A doping concentration at a concentration peak refers to a doping concentration at a local maximum of the concentration peak. In addition, as the doping concentration of the drift region 18, an average value of doping concentrations in a region where a doping concentration distribution is substantially flat may be used.

The buffer region 20 may have two or more concentration peaks in the depth direction (the Z axis direction) of the semiconductor substrate 10. The concentration peak of the buffer region 20 may be provided, for example, at the same depth position as that of a chemical concentration peak of hydrogen (a proton) or phosphorous. The buffer region 20 may function as a field stopper layer which prevents a depletion layer expanding from a lower end of the base region 14 from reaching the collector region 22 of the P+ type and the cathode region 82 of the N+ type.

In the transistor portion 70, the collector region 22 of the P+ type is provided below the buffer region 20. An acceptor concentration of the collector region 22 is higher than an acceptor concentration of the base region 14. The collector region 22 may include an acceptor which is the same as or different from an acceptor of the base region 14. The acceptor of the collector region 22 is, for example, boron.

Below the buffer region 20 in the diode portion 80, the cathode region 82 of the N+ type is provided. A donor concentration of the cathode region 82 is higher than a donor concentration of the drift region 18. A donor of the cathode region 82 is, for example, hydrogen or phosphorous. It should be noted that an element serving as a donor and an acceptor in each region is not limited to the example described above. The collector region 22 and the cathode region 82 are exposed to the lower surface 23 of the semiconductor substrate 10 and are connected to the collector electrode 24. The collector electrode 24 may be in contact with the entire lower surface 23 of the semiconductor substrate 10. The emitter electrode 52 and the collector electrode 24 are formed of a metal material such as aluminum.

One or more gate trench portions 40 and one or more dummy trench portions 30 are provided at the upper surface 21 side of the semiconductor substrate 10. Each trench portion passes through the base region 14, and is provided from the upper surface 21 of the semiconductor substrate 10 to a region below the base region 14. In a region where at least any of the emitter region 12, the contact region 15, or the accumulation region 16 is provided, each trench portion also passes through the doping regions of these. A structure in which the trench portion passes through the doping region is not limited to a structure which is made by forming the doping region and then forming the trench portion in order. A structure in which the trench portion is formed and then the doping region is formed between the trench portions is also included in the structure in which the trench portion passes through the doping region.

As described above, the transistor portion 70 is provided with the gate trench portion 40 and the dummy trench portion 30. The diode portion 80 is provided with the dummy trench portion 30, and is not provided with the gate trench portion 40. A boundary between the diode portion 80 and the transistor portion 70 in the X axis direction, in the present example, is a boundary between the cathode region 82 and the collector region 22.

The gate trench portion 40 includes a gate trench provided in the upper surface 21 of the semiconductor substrate 10, a gate dielectric film 42, and a gate conductive portion 44. The gate dielectric film 42 is provided to cover an inner wall of the gate trench. The gate dielectric film 42 may be formed by oxidizing or nitriding a semiconductor at the inner wall of the gate trench. The gate conductive portion 44 is provided farther inward than the gate dielectric film 42 inside the gate trench. In other words, the gate dielectric film 42 insulates the gate conductive portion 44 from the semiconductor substrate 10. The gate conductive portion 44 is formed of a conductive material such as polysilicon.

The gate conductive portion 44 may be provided to be longer than the base region 14 in the depth direction. The gate trench portion 40 in the cross section is covered by the interlayer dielectric film 38 on the upper surface 21 of the semiconductor substrate 10. The gate conductive portion 44 is electrically connected to the gate runner. When a predetermined gate voltage is applied to the gate conductive portion 44, a channel is formed by an electron inversion layer in a surface layer of the base region 14 at a boundary in contact with the gate trench portion 40.

The dummy trench portions 30 may have the same structure as that of the gate trench portions 40 in the cross section. The dummy trench portion 30 includes a dummy trench provided in the upper surface 21 of the semiconductor substrate 10, a dummy dielectric film 32, and a dummy conductive portion 34. The dummy conductive portion 34 is electrically connected to the emitter electrode 52. The dummy dielectric film 32 is provided to cover an inner wall of the dummy trench. The dummy conductive portion 34 is provided inside the dummy trench, and is provided farther inward than the dummy dielectric film 32. The dummy dielectric film 32 insulates the dummy conductive portion 34 from the semiconductor substrate 10. The dummy conductive portion 34 may be formed of the same material as that of the gate conductive portion 44. For example, the dummy conductive portion 34 is formed of a conductive material such as polysilicon. The dummy conductive portion 34 may have the same length as that of the gate conductive portion 44 in the depth direction.

The gate trench portion 40 and the dummy trench portion 30 in the present example are covered with the interlayer dielectric film 38 on the upper surface 21 of the semiconductor substrate 10. It should be noted that bottom portions of the dummy trench portion 30 and the gate trench portion 40 may have curved surfaces which are convex downward (curved shapes in the cross sections).

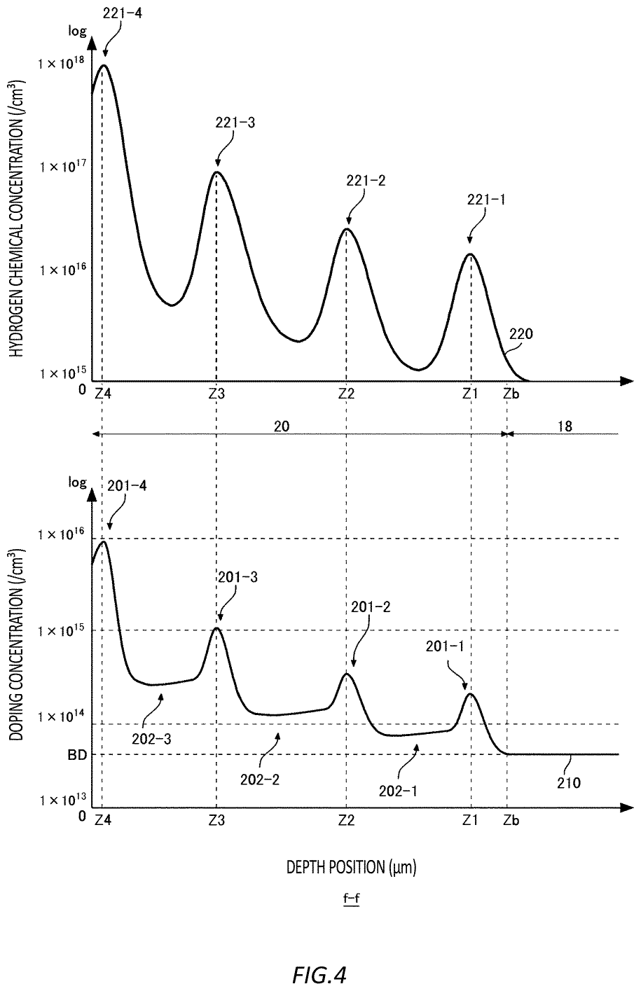

FIG. 4 is a diagram showing an example of a distribution 220 of a hydrogen chemical concentration and a distribution 210 of a doping concentration in line f-f of FIG. 3. In concentration distribution graphs in FIG. 4 or the like, a carrier concentration measured by the SRP method or the like is used as the doping concentration. A vertical axis in FIG. 4 represents a scale of a common logarithm (log) for both the distribution 220 of the hydrogen chemical concentration and the distribution 210 of the doping concentration. A horizontal axis (depth position) in FIG. 4 is a linear scale. Line f-f is a line parallel to the Z axis passing through the buffer region 20. The horizontal axis in FIG. 4 represents a depth position (a position in the Z axis direction) in the semiconductor substrate 10. In the concentration distribution graphs in FIG. 4 or the like, a lower end position of the buffer region 20 is defined as a reference position (0) in the Z axis direction, and a distance from the reference position is defined as a position in the Z axis direction. At the lower end position of the buffer region 20, there is a valley of the doping concentration distribution due to a PN junction of the collector region 22 and the buffer region 20, but the valley is omitted in FIG. 4 or the like.

The entire semiconductor substrate 10 contains a bulk donor. A concentration of the bulk donor is denoted as BD. A doping concentration of the drift region 18 may be the same as or different from the bulk donor concentration BD. The buffer region 20 has a higher doping concentration than that of the drift region 18.

The semiconductor substrate 10 has a plurality of hydrogen concentration peaks 221 arranged side by side in the depth direction. The hydrogen concentration peak 221 is a mountain-shaped portion of the distribution 220 in which the hydrogen chemical concentration exhibits a local maximum value in the depth direction. One or more hydrogen concentration peaks 221 may be provided in the buffer region 20. At least one hydrogen concentration peak 221 may be provided on the upper surface 21 side with respect to the buffer region 20. In the present example, all hydrogen concentration peaks 221 are provided in the buffer region 20.

The semiconductor substrate 10 has a plurality of doping concentration peaks 201 arranged corresponding to the plurality of hydrogen concentration peaks 221. The doping concentration peak 201 is a mountain-shaped portion of the distribution 210 in which the doping concentration exhibits a local maximum value in the depth direction. A number of the doping concentration peaks 201 may be 2 or more, 3 or more, 4 or more, or 5 or more. In a region where the hydrogen chemical concentration is high, many hydrogen donors are formed, so that the doping concentration peak 201 is formed corresponding to the hydrogen concentration peak 221. The doping concentration peak 201 may be provided for at least one hydrogen concentration peak 221. In the present example, the doping concentration peaks 201 are provided for all the hydrogen concentration peaks 221.

Among the plurality of doping concentration peaks 201 corresponding to the hydrogen concentration peaks 221, a peak farthest from the lower surface 23 is defined as a first doping concentration peak 201-1, and a peak second farthest from the lower surface 23 is defined as a second doping concentration peak 201-2. Similarly, a peak k-th farthest from the lower surface 23 is defined as a k-th doping concentration peak 201-k. In addition, a region between the k-th doping concentration peak 201-k and a (k+1)-th doping concentration peak 201-(k+1) is defined as a k-th inter-peak region 202-k. An inter-peak region 202 may include a portion where the doping concentration exhibits a local minimum value. A doping concentration of the inter-peak region 202 is also higher than the doping concentration of the drift region 18.

A correspondence between the hydrogen concentration peak 221 and the doping concentration peak 201 may indicate that a local maximum of one of the concentration peaks is arranged within a full width at half maximum of another of the concentration peaks. When the hydrogen concentration peak 221 and the doping concentration peak 201 correspond to each other, a distance between local maxima of these two corresponding concentration peaks may be 2 μm or less, 1 μm or less, or 0.5 μm or less.

At least one doping concentration peak 201 may be provided in the buffer region 20. The first doping concentration peak 201-1 may be arranged in the buffer region 20. All the doping concentration peaks 201 may be arranged in the buffer region 20.

The buffer region 20 may or may not have a doping concentration peak other than the doping concentration peak 201. That is, the buffer region 20 may or may not have a doping concentration peak formed by donors other than hydrogen donors. All doping concentration peaks of the buffer region 20 in the present example are the doping concentration peaks 201 formed with hydrogen donors. In a concentration distribution example other than FIG. 4, the distribution 220 of the hydrogen chemical concentration is omitted, but the hydrogen concentration peaks 221 are provided for all the doping concentration peaks 201.

By implanting hydrogen ions into the semiconductor substrate 10, hydrogen donors are formed in a vicinity of an implantation position of the hydrogen ions and in a region through which the hydrogen ions have passed. In the example of FIG. 4, hydrogen ions are implanted into depth positions Z1, Z2, Z3, and Z4 from the lower surface 23. High-concentration hydrogen donors are formed in a vicinity of the depth positions Z1 to Z4, and hydrogen donors are also formed in a passed-through region from the lower surface 23 to the depth position Z1. With this configuration, a plurality of doping concentration peaks 201 and one or more inter-peak regions 202 are formed. Hydrogen ions may be implanted from the upper surface 21 of the semiconductor substrate 10.

A doping concentration of each region of the semiconductor substrate 10 affects characteristics of the semiconductor device 100. For example, the doping concentration of the buffer region 20 affects a breakdown voltage of the semiconductor device 100. Therefore, it is preferable that a variation in a concentration of hydrogen donors formed by implanting hydrogen ions is small. However, the concentration of hydrogen donors fluctuates depending on a carbon concentration of the semiconductor device 100 or the like. In particular, in the MCZ substrate having a high oxygen concentration, a variation in the concentration of hydrogen donors due to a variation in carbon concentration tends to increase.

The hydrogen donor includes an interstitial Si—H donor and a CiOi-H donor. Since the CiOi-H donor contains carbon, a CiOi-H donor concentration is affected by a carbon chemical concentration of the semiconductor substrate 10. On the other hand, an interstitial Si—H donor concentration is relatively less affected by the carbon chemical concentration of the semiconductor substrate 10. Therefore, by relatively increasing the interstitial Si—H donor concentration and relatively decreasing the CiOi-H donor concentration, an influence of the carbon chemical concentration of the semiconductor substrate 10 can be reduced, and the concentration of hydrogen donors can be accurately controlled.

When hydrogen ions are implanted into the semiconductor substrate 10 having different carbon chemical concentrations under a same implantation condition, an increase amount of the doping concentration at the doping concentration peak 201 exhibits relatively small fluctuations depending on the carbon chemical concentration, and an increase amount of the doping concentration in the inter-peak region 202 exhibits relatively large fluctuations depending on the carbon chemical concentration. The increase amount of the doping concentration corresponds to the concentration of hydrogen donors formed by implanting hydrogen ions. Therefore, it is estimated that the doping concentration peak 201 is mainly formed by the interstitial Si—H donors, and the inter-peak region 202 is mainly formed by the CiOi-H donors. Therefore, the concentrations of the interstitial Si—H donor and the CiOi-H donor can be estimated from the increase amount of the doping concentration in the doping concentration peak 201 and the inter-peak region 202. As the increase amount of the doping concentration, a value obtained by subtracting the bulk donor concentration BD from the doping concentration at a target position may be used, or a value obtained by subtracting the doping concentration of the drift region 18 from the doping concentration at the target position may be used.

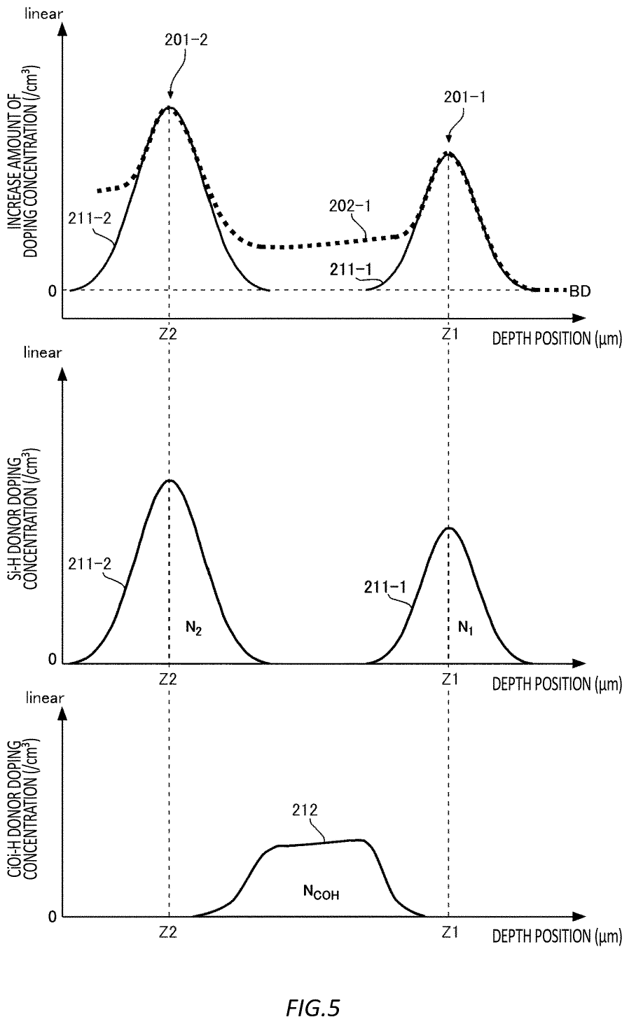

FIG. 5 is a diagram explaining a method for estimating the concentrations of the interstitial Si—H donor and the CiOi-H donor. Each vertical axis in FIG. 5 represents the doping concentration or the increase amount thereof, and any vertical axis is a linear scale. In the present example, the concentrations of the interstitial Si—H donor and the CiOi-H donor in the first doping concentration peak 201-1 and a first inter-peak region 202-1 are estimated. In an upper graph of FIG. 5, a distribution of the increase amount of the doping concentration in the first doping concentration peak 201-1, the first inter-peak region 202-1, and the second doping concentration peak 201-2 is indicated by a broken line. The increase amount of the doping concentration in the present example is an increase amount of the doping concentration based on the bulk donor concentration BD. As described above, the increase amount of the doping concentration corresponds to the concentration of hydrogen donors.

The first doping concentration peak 201-1 is fitted with a Gaussian distribution 211-1, and the second doping concentration peak 201-2 is fitted with a Gaussian distribution 211-2. Each Gaussian distribution 211 may have a predetermined half width at half maximum. The half width at half maximum is, for example, 2.47 μm. In another example, a full width at half maximum of a hydrogen concentration peak 221-k corresponding to each doping concentration peak 201-k may be used as a full width at half maximum of each Gaussian distribution 211-k. In addition, a full width at half maximum of each doping concentration peak 201-k may be used as the full width at half maximum of each Gaussian distribution 211-k. Fitting may be performed by applying a depth position and a local maximum concentration of each doping concentration peak 201 to the Gaussian distribution 211.

An integrated concentration N_{K} obtained by integrating the concentration of each Gaussian distribution 211-k in the depth direction corresponds to the integrated concentration N_{K}of the interstitial Si—H donors at each doping concentration peak 201-k. In the example of FIG. 5, an integrated concentration of the interstitial Si—H donors included in the first doping concentration peak 201-1 is N₁, and an integrated concentration of the interstitial Si—H donors included in the second doping concentration peak 201-2 is N₂.

In a region from the depth position Z1 to the depth position Z2, a residual distribution 212 obtained by subtracting the Gaussian distribution 211-1 and the Gaussian distribution 211-2 from the distribution of the increase amount of the doping concentration corresponds to a CiOi-H donor concentration distribution. The integrated concentration N_{COH} obtained by integrating a concentration of the residual distribution 212 in the depth direction corresponds to the integrated concentration N_{COH} of the CiOi-H donors in the region from the depth position Z1 to the depth position Z2.

By such processing, the integrated concentrations of the interstitial Si—H donors and the CiOi-H donors in the region from the depth position Z1 to the depth position Z2 can be estimated. In the present specification, an integrated value N of a hydrogen donor concentration in the region is N=N₁+N_{COH}. In addition, a ratio of the CiOi-H donor is denoted as N_{COH}/N. Note that, also in a region from each depth position Zk to a depth position Z(k+1), the integrated concentrations of the interstitial Si—H donors and the CiOi-H donors can be similarly estimated.

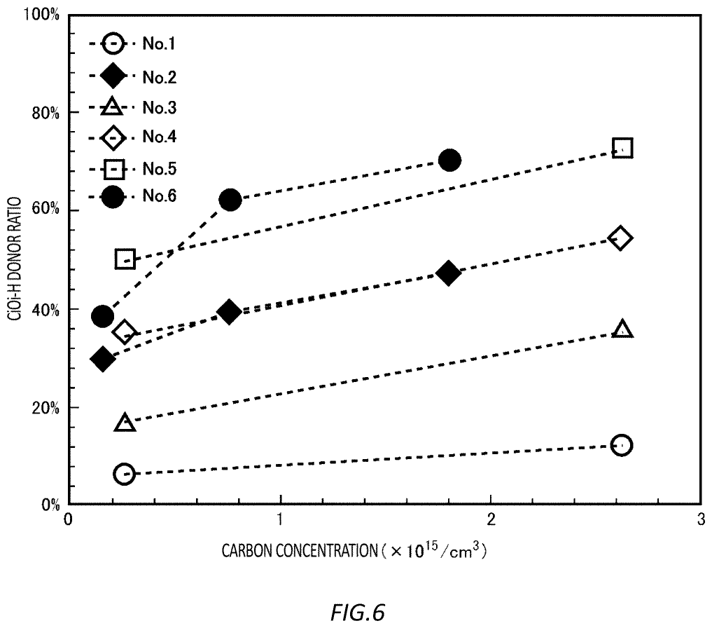

FIG. 6 is a diagram showing a result of measuring the ratio of the CiOi-H donor. In the example of FIG. 6, the ratio N_{COH}/N of the CiOi-H donor is measured for a plurality of types of semiconductor devices 100 which differ in each of the hydrogen ion implantation condition and the carbon chemical concentration of the semiconductor substrate 10. Unless otherwise described in the present specification, the ratio of the CiOi-H donor refers to a ratio in the region from the depth position Z1 to Z2 described above. In FIG. 6, a horizontal axis represents the carbon chemical concentration of the semiconductor substrate 10, and a vertical axis represents the CiOi-H donor ratio. In addition, as the hydrogen ion implantation condition, six kinds of Conditions No. 1 to No. 6 are used. In the implantation condition with a smaller number, at least one of a number of steps of the depth position where hydrogen ions are implanted or a dose amount of hydrogen ions with respect to each depth position is larger than in the implantation condition with a larger number. That is, under the implantation condition with a smaller number, a number of the hydrogen concentration peaks 221 tends to be larger, and a local maximum concentration of the hydrogen concentration peak 221 tends to be higher.

As shown in FIG. 6, as the number of the implantation condition decreases, the CiOi-H donor ratio decreases. That is, the CiOi-H donor ratio can be controlled by the hydrogen ion implantation condition.

As shown in FIG. 6, as the carbon chemical concentration of the semiconductor substrate 10 increases, the CiOi-H donor ratio increases. However, as shown in Implantation Conditions No. 2 and No. 6, the CiOi-H donor ratio tends to saturate as the carbon chemical concentration increases. In another implantation condition, there is no measurement result of a sample in which the carbon chemical concentration exhibits an intermediate value, but it is presumed that a tendency similar to that in Implantation Conditions No. 2 and No. 6 is shown. The CiOi-H donor also contains oxygen. Therefore, an oxygen chemical concentration of the semiconductor substrate 10 may also affect the concentration of the CiOi-H donor.

The oxygen chemical concentration of the semiconductor substrate 10 under each condition of the present example is 1×10¹⁷/cm³ or more and 5×10¹⁷/cm³ or less. On the other hand, the carbon chemical concentration of the semiconductor substrate 10 is 0.26×10¹⁵/cm³ or more and 2.6×10¹⁵/cm³ or less. Therefore, the oxygen chemical concentration is sufficiently higher than the carbon chemical concentration. However, when a contribution rate of oxygen to formation of the CiOi-H donor is relatively low, it is also conceivable that the concentration of the CiOi-H donor is limited by the oxygen chemical concentration. Similarly, it is conceivable that the concentration of the CiOi-H donor is limited by the hydrogen chemical concentration. For this reason, it is conceivable that the CiOi-H donor ratio tends to saturate as the carbon chemical concentration increases.

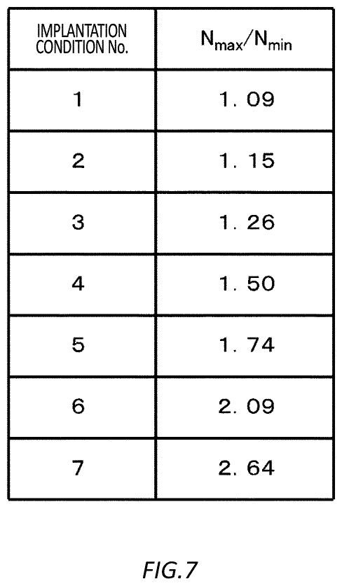

FIG. 7 is a diagram showing a variation Nₘₐₓ/Nₘᵢₙ of the integrated value N of the hydrogen donor concentration under each implantation condition. In FIG. 7, in addition to Conditions No. 1 to No. 6 described in FIG. 6, condition No. 7 is also shown. In the implantation condition with a small number including Condition No. 7, at least one of the number of steps of the depth position where hydrogen ions are implanted or the dose amount of hydrogen ions with respect to each depth position is larger than that in the implantation condition with a large number. A maximum value of the integrated value N of the hydrogen donor concentration under each implantation condition is denoted as Nₘₐₓ, and a minimum value thereof is denoted as Nₘᵢₙ. As the carbon chemical concentration of the semiconductor substrate 10 is higher, more hydrogen donors tend to be formed. In the example of FIG. 6, under each implantation condition, the integrated value N of a sample having a minimum carbon chemical concentration of the semiconductor substrate 10 is the minimum value Nₘᵢₙ, and the integrated value N of a sample having a maximum carbon chemical concentration of the semiconductor substrate 10 is the maximum value Nₘₐₓ. As shown in FIGS. 6 and 7, under the implantation condition where the CiOi-H donor ratio is lower, the variation Nₘₐₓ/Nₘᵢₙ of the integrated value N of the hydrogen donor concentration decreases.

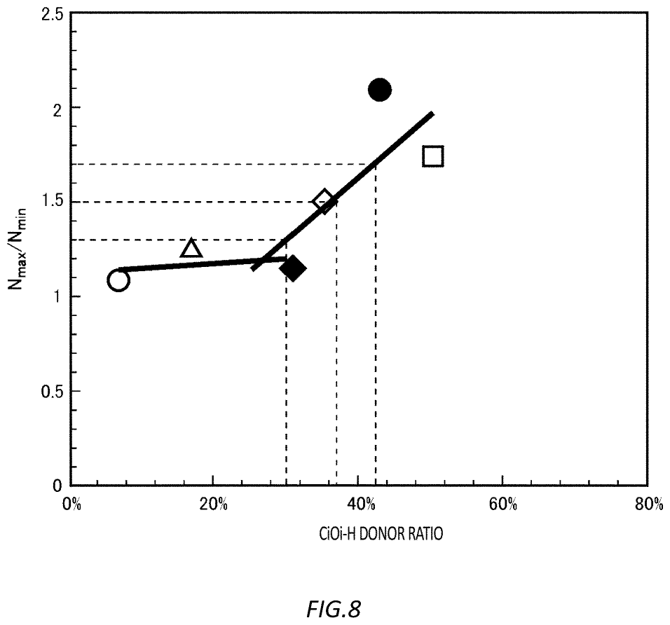

FIG. 8 is a diagram showing a relationship between the CiOi-H donor ratio and the variation Nₘₐₓ/Nₘᵢₙ of the integrated value N of the hydrogen donor concentration. FIG. 8 shows a relationship when the carbon chemical concentration of the semiconductor substrate 10 is 0.26×10¹⁵/cm³.

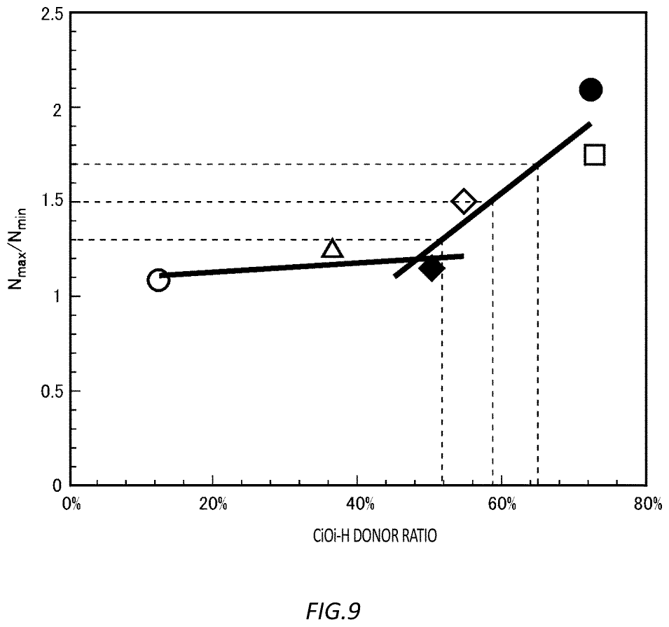

FIG. 9 is a diagram showing the relationship between the CiOi-H donor ratio and the variation Nₘₐₓ/Nₘᵢₙ of the integrated value N of the hydrogen donor concentration. FIG. 9 shows a relationship when the carbon chemical concentration of the semiconductor substrate 10 is 2.6×10¹⁵/cm³. A type of a mark in each plot in FIGS. 8 and 9 indicates the hydrogen ion implantation condition similarly to the example in FIG. 7. As a value of the variation Nₘₐₓ/Nₘᵢₙ under each implantation condition, the value shown in FIG. 7 is used.

For Conditions No. 2 and No. 6, there is no measurement result when the carbon chemical concentration is 2.6×10¹⁵/cm³, and thus estimated values are used. As shown in FIG. 6, the CiOi-H donor ratio tends to saturate as the carbon chemical concentration increases. In addition, as shown in FIGS. 6 and 7, the variation Nₘₐₓ/Nₘᵢₙ decreases according to the CiOi-H donor ratio. Therefore, Nₘₐₓ/Nₘᵢₙ was approximated by a function of Nₘₐₓ/Nₘᵢₙ=A−B×exp(−C×[C]) to calculate the estimated values. A, B, and C are constants, and [C] is the carbon chemical concentration.

As shown in FIG. 8, when the carbon chemical concentration of the semiconductor substrate 10 is 0.26×10¹⁵/cm³, if the CiOi-H donor ratio is set to about 42%, the variation Nₘₐₓ/Nₘᵢₙ can be set to 1.7. Similarly, if the CiOi-H donor ratio is set to about 37%, the variation Nₘₐₓ/Nₘᵢₙ can be set to 1.5. Similarly, if the CiOi-H donor ratio is set to about 30%, the variation Nₘₐₓ/Nₘᵢₙ can be set to 1.3.

As shown in FIG. 9, when the carbon chemical concentration of the semiconductor substrate 10 is 2.6×10¹⁵/cm³, if the CiOi-H donor ratio is set to about 65%, the variation Nₘₐₓ/Nₘᵢₙ can be set to 1.7. Similarly, if the CiOi-H donor ratio is set to about 59%, the variation Nₘₐₓ/Nₘᵢₙ can be set to 1.5. Similarly, if the CiOi-H donor ratio is set to about 50%, the variation Nₘₐₓ/Nₘᵢₙ can be set to 1.3. In any of the examples of FIGS. 8 and 9, it is found that an increase in the variation Nₘₐₓ/Nₘᵢₙ can be particularly suppressed by setting the CiOi-H donor ratio such that the variation Nₘₐₓ/Nₘᵢₙ is smaller than 1.3.

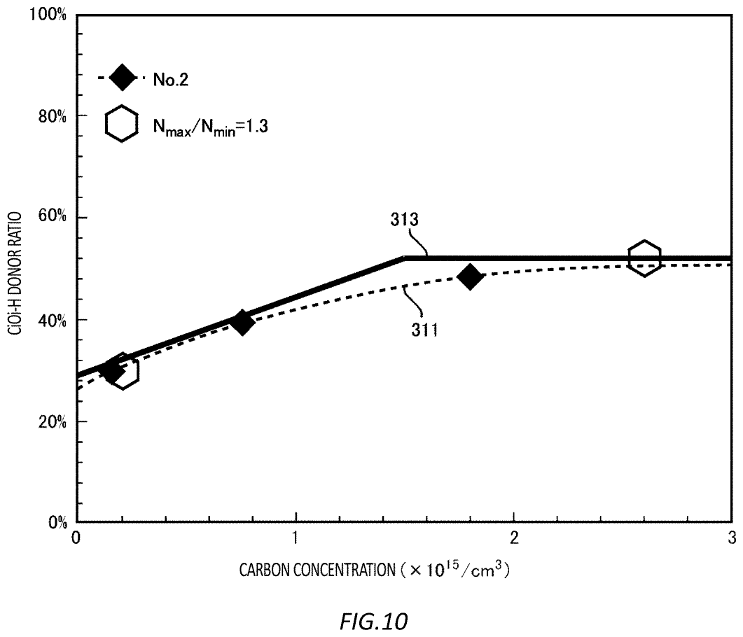

FIG. 10 is a diagram in which the CiOi-H donor ratio at each carbon chemical concentration is plotted by a hexagonal mark when the variation Nₘₐₓ/Nₘᵢₙ is set to 1.3. As described in FIG. 8, when the carbon chemical concentration of the semiconductor substrate 10 is 0.26×10¹⁵/cm³, the CiOi-H donor ratio for setting the variation Nₘₐₓ/Nₘᵢₙ to 1.3 is 30%. As described in FIG. 9, when the carbon chemical concentration of the semiconductor substrate 10 is 2.6×10¹⁵/cm³, the CiOi-H donor ratio for setting the variation Nₘₐₓ/Nₘᵢₙ to 1.3 is 50%.

FIG. 10 also shows an example in which the hydrogen ion implantation condition is No. 2. A curve 311 is a curve obtained by approximating the plot of condition No. 2 with a function of N_{COH}/N=A−B×exp(−C×[C]). As shown in FIG. 10, a position of a hexagonal plot substantially coincides with the curve 311. By setting the CiOi-H donor ratio to a value indicated by the curve 311 or less, the variation Nₘₐₓ/Nₘᵢₙ can be suppressed to 1.3 or less.

In the present example, in an entire region where the carbon chemical concentration of the semiconductor substrate 10 is 5×10¹⁵/cm³ or less, a boundary line 313 where the CiOi-H donor ratio is slightly higher than that of the curve 311 is introduced. By setting the CiOi-H donor ratio to a value indicated by the boundary line 313 or less, the variation Nₘₐₓ/Nₘᵢₙ can be more reliably suppressed to 1.3 or less. The carbon chemical concentration of the semiconductor substrate 10 of the semiconductor device 100 may be 5×10¹⁵/cm³ or less. The carbon chemical concentration of the semiconductor substrate 10 of the semiconductor device 100 may be 4×10¹⁵/cm³ or less, or may be 3×10¹⁵/cm³ or less. The carbon chemical concentration of the semiconductor substrate 10 of the semiconductor device 100 may be 0.1×10¹⁵/cm³ or more, or may be 0.2×10¹⁵/cm³ or more.

The CiOi-H donor ratio tends to saturate as the carbon chemical concentration increases, and thus the CiOi-H donor ratio at the boundary line 313 was constant in a region where the carbon chemical concentration was larger than 1.5×10¹⁵/cm³. In the present example, a condition that the CiOi-H donor ratio N_{COH}/N is lower than that of the boundary line 313 is expressed by (Conditional Expression 1).

When N_{C}≤1.5×10¹⁵/cm³,

N_{COH}/N≤0.133×N_{C}×10⁻¹⁵+0.3, and

when N_{C}>1.5×10¹⁵/cm³,

N_{COH}/N≤0.5, (Conditional Expression 1)
where N_{C} is the carbon chemical concentration of the semiconductor substrate 10, N_{COH} is the integrated concentration of the residual distribution 212 described in FIG. 5 (corresponding to the integrated concentration of the CiOi-H donors), and N=N₁+N_{COH}. N₁ is the integrated concentration of the Si—H donors at the first doping concentration peak 201-1 described in FIG. 5. N_{C} may be an average value of the carbon chemical concentrations in the entire semiconductor substrate 10.

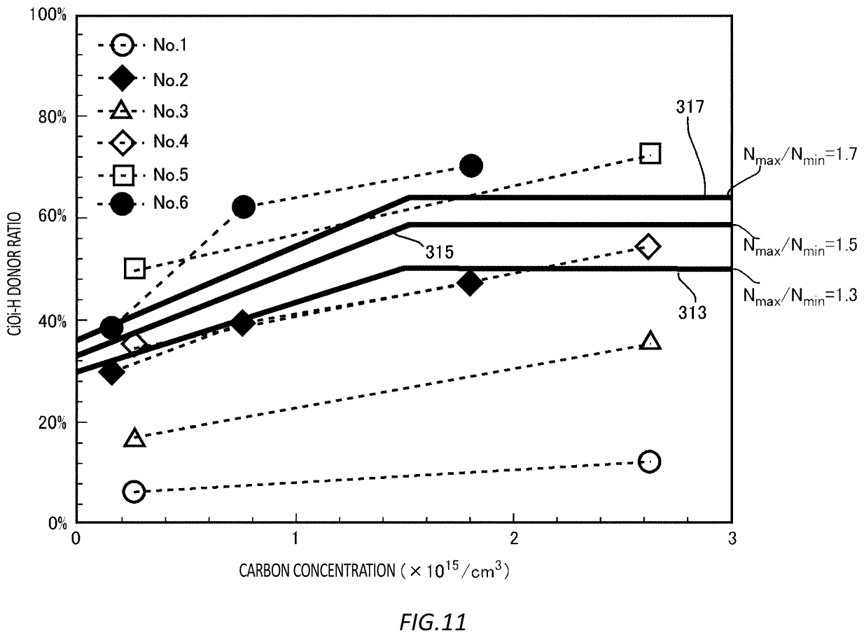

FIG. 11 is a diagram showing a boundary line corresponding to a condition for setting the variation Nₘₐₓ/Nₘᵢₙ to 1.7 or less, 1.5 or less, or 1.3 or less. The boundary line 313 indicates a condition for setting the variation Nₘₐₓ/Nₘᵢₙ to 1.3 or less, a boundary line 315 indicates a condition for setting the variation Nₘₐₓ/Nₘᵢₙ to 1.5 or less, and a boundary line 317 indicates a condition for setting the variation Nₘₐₓ/Nₘᵢₙ to 1.7 or less. As described in FIG. 10 or the like, in the region where the carbon chemical concentration was larger than 1.5×10¹⁵/cm³, the CiOi-H donor ratio at each boundary line was constant. The CiOi-H donor ratio in the region corresponds to the CiOi-H donor ratio described in FIG. 9. In a region where the carbon chemical concentration was 1.5×10¹⁵/cm³ or less, each region was set on assumption that the CiOi-H donor ratio linearly increased according to an increase in the carbon chemical concentration.

By making the CiOi-H donor ratio N_{COH}/N lower than that of the boundary line 315, the variation Nₘₐₓ/Nₘᵢₙ can be suppressed to 1.5 or less. In the present example, a condition that the CiOi-H donor ratio is lower than that of the boundary line 315 is expressed by (Conditional Expression 2).

When N_{C}≤1.5×10¹⁵/cm³,

N_{COH}/N≤0.173×N_{C}×10⁻¹⁵+0.33, and

when N_{C}>1.5×10¹⁵/cm³,

N_{COH}/N≤0.59 (Conditional Expression 2)

By making the CiOi-H donor ratio N_{COH}/N lower than the boundary line 317, the variation Nₘₐₓ/Nₘᵢₙ can be suppressed to 1.7 or less. In the present example, a condition that the CiOi-H donor ratio is lower than that of the boundary line 317 is expressed by (Conditional Expression 3).

When N_{C}≤1.5×10¹⁵/cm³,

N_{COH}/N≤0.2×N_{C}×10⁻¹⁵+0.35, and

when N_{C}>1.5×10¹⁵/cm³,

N_{COH}/N≤0.65 (Conditional Expression 3)

The semiconductor device 100 may satisfy Conditional Expression 3, Conditional Expression 2, or Conditional Expression 1.

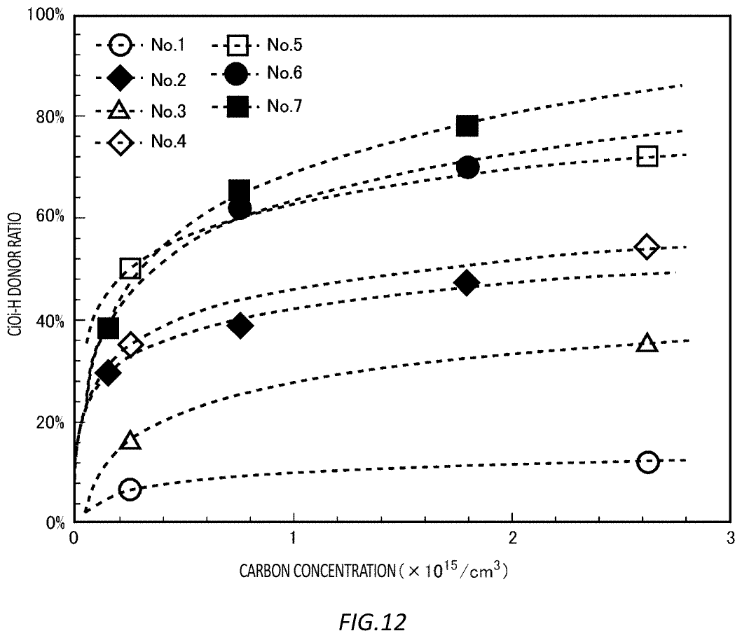

FIG. 12 is a diagram showing a curve obtained by fitting the CiOi-H donor ratio with a common logarithm of the carbon concentration for each condition of Implantation Conditions 1 to 7. Implantation Conditions 1 to 7 are Conditions No. 1 to No. 7 shown in FIG. 7. When the CiOi-H donor ratio can be 50% or less, the variation Nₘₐₓ/Nₘᵢₙ can be reliably 1.7 or less. That is, when the relationship between the CiOi-H donor ratio and the carbon chemical concentration lies below the curve of Implantation Condition 4, the variation Nₘₐₓ/Nₘᵢₙ can be sufficiently reduced. A condition that the CiOi-H donor ratio is lower than that of the curve of Condition 4 is expressed by (Conditional Expression 4). Note that In is a natural logarithm with a base of e.

N_{COH}/N≤8.286×10⁻²×In(N_{C})+0.4656 (Conditional Expression 4)

Further, when the relationship between the CiOi-H donor ratio and the carbon chemical concentration lies below the curve of Implantation Condition 2, the variation Nₘₐₓ/Nₘᵢₙ can be sufficiently reduced. A condition that the CiOi-H donor ratio is lower than that of the curve of Condition 2 is expressed by (Conditional Expression 5).

N_{COH}/N≤7.185×10⁻²×In(N_{C})+0.4260 (Conditional Expression 5)

The semiconductor device 100 may satisfy Conditional Expression 4. The semiconductor device 100 may satisfy Conditional Expression 5.

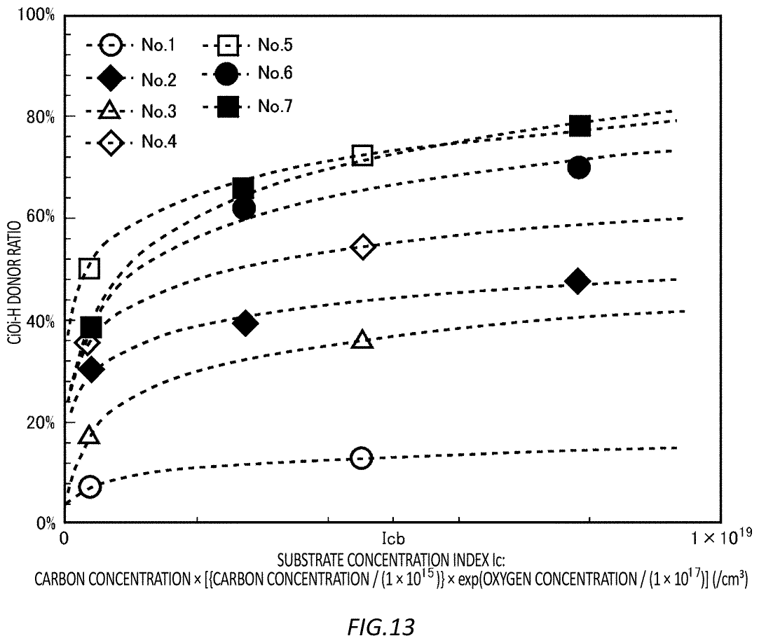

FIG. 13 is a diagram in which the CiOi-H donor ratio is plotted with a substrate concentration index Ic as a horizontal axis for each condition of Implantation Conditions 1 to 7. The substrate concentration index Ic is defined by a following expression when the oxygen chemical concentration of the semiconductor substrate 10 is denoted as N_{OX} (/cm³) and the carbon chemical concentration of the semiconductor substrate 10 is denoted as N_{C} (/cm³).

I_{C}=(N_{OX}×[{N_{C}/(1E15)}×exp(N_{OX}/(1E17))])

A unit of the substrate concentration index Ic defined by the above expression is (cm⁻³). The oxygen chemical concentration N_{OX} of the semiconductor substrate 10 may be an oxygen chemical concentration of the drift region 18. The carbon chemical concentration N_{C} of the semiconductor substrate 10 may be a carbon chemical concentration of the drift region 18. Note that the substrate concentration index Ic may be defined by another mathematical formula as long as it relates to at least one of the oxygen chemical concentration or the carbon chemical concentration. The substrate concentration index Ic is an index in consideration of an influence of the oxygen chemical concentration N_{OX} and an influence of the carbon chemical concentration N_{C} on generation of the CiOi-H donor.

The oxygen chemical concentration N_{OX} is assumed to contribute to the concentration of the CiOi-H donor generated in a passed-through region of hydrogen ions. Further, in order to consider the influence of the carbon chemical concentration N_{C}, a correction factor is applied to the oxygen chemical concentration N_{OX}. The correction factor means the influence of the carbon chemical concentration N_{C} on the generation of the CiOi-H donor. Further, the correction factor assumes a model in which the influence of the carbon chemical concentration N_{C} depends on the oxygen chemical concentration N_{OX}. That is, a normalized carbon chemical concentration obtained by normalizing the carbon chemical concentration N_{C} at a predetermined carbon chemical concentration (here, 1×10¹⁵/cm³) is multiplied by a value determined by an exponential function of a normalized oxygen chemical concentration obtained by normalizing the oxygen chemical concentration N_{OX} at a predetermined oxygen chemical concentration (here, 1×10¹⁷/cm³). This model can be analyzed in consideration of an influence of a correlation between the oxygen chemical concentration and the carbon chemical concentration on the CiOi-H donor ratio.

As shown in FIG. 13, also in the substrate concentration index Ic, for example, when a boundary value Icb of the substrate concentration index Ic is 5×101⁸ (/cm³) and the substrate concentration index Ic is larger than the boundary value Icb, it can be seen that an increase rate of the CiOi-H donor ratio is slow. That is, in a case of the substrate concentration index Ic including not only the carbon chemical concentration but also the oxygen chemical concentration, characteristics of the CiOi-H donor ratio before and after the boundary value are similar. Thus, in the conditional expression, the influence of the carbon chemical concentration N_{C} may be used, or the influence of the substrate concentration index Ic may be used.

As shown in FIG. 13, when the relationship between the CiOi-H donor ratio and the carbon chemical concentration lies below the curve of Implantation Condition 4, the variation Nₘₐₓ/Nₘᵢₙ can be sufficiently reduced. A condition that the CiOi-H donor ratio is lower than that of the curve of Condition 4 is expressed by (Conditional Expression 6).

N_{COH}/N≤8.080×10⁻²×In(I_{C})−2.926 (Conditional Expression 6)

Further, when the relationship between the CiOi-H donor ratio and the carbon chemical concentration lies below the curve of Implantation Condition 2, the variation Nₘₐₓ/Nₘᵢₙ can be sufficiently reduced. A condition that the CiOi-H donor ratio is lower than that of the curve of Condition 2 is expressed by (Conditional Expression 7).

N_{COH}/N≤6.120×10⁻²×In(I_{C})−2.194 (Conditional Expression 7)

The semiconductor device 100 may satisfy Conditional Expression 6 or Conditional Expression 7.

The CiOi-H donor ratio N_{COH}/N of the semiconductor device 100 can be adjusted under the hydrogen ion implantation condition as described with reference to FIGS. 5 to 7. For example, as shown in FIG. 5, by reducing a distance (Z1−Z2) between the first doping concentration peak 201-1 and the second doping concentration peak 201-2, a width of the inter-peak region 202 in the Z axis direction is reduced, so that the CiOi-H donor ratio is reduced. In addition, by making the depth position Z1 of the first doping concentration peak 201-1 deep, the first doping concentration peak 201-1 becomes gentle, the doping concentration in the inter-peak region 202 increases, and the CiOi-H donor ratio increases. In addition, by increasing the doping concentration (/cm³) at the local maximum of the first doping concentration peak 201-1 or the dose amount (/cm²) of hydrogen ions for forming the first doping concentration peak 201-1, the concentration of the Si—H donor increases, and the CiOi-H donor ratio can be reduced. In addition, by adjusting annealing conditions after hydrogen ions are implanted, a degree of diffusion of hydrogen inside the semiconductor substrate 10 can be adjusted, and the CiOi-H donor ratio can be adjusted. For example, by increasing an annealing temperature or increasing an annealing time, an amount of hydrogen diffused into the inter-peak region 202 can be increased to increase the doping concentration in the inter-peak region 202, and the CiOi-H donor ratio can be adjusted.

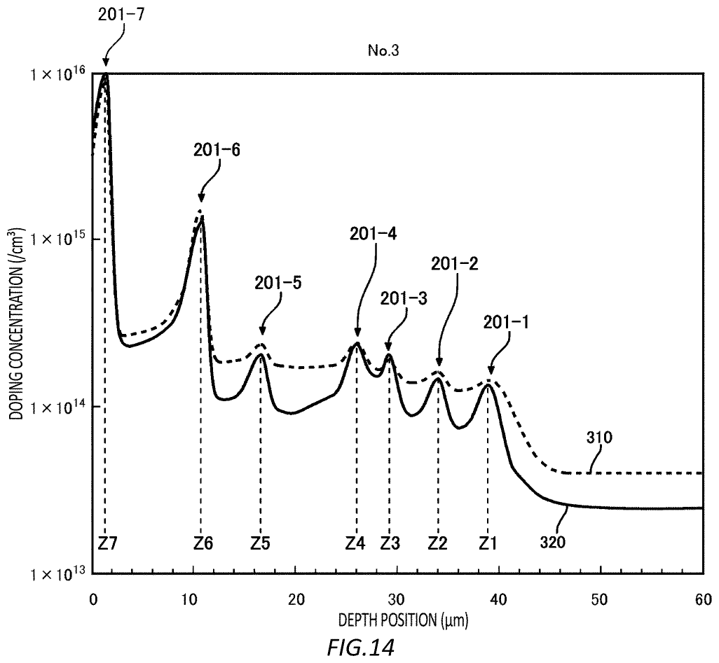

FIG. 14 is a diagram showing an example of a doping concentration distribution of the buffer region 20 according to one embodiment of the present invention. The buffer region 20 of the present example is formed by implanting hydrogen ions under Condition No. 3. In addition, an example in which the carbon chemical concentration of the semiconductor substrate 10 is 2.6×10¹⁵/cm³ is indicated by a distribution 310 (dotted line), and an example in which the carbon chemical concentration is 0.26×10¹⁵/cm³ is indicated by a distribution 320 (solid line). The hydrogen ion implantation conditions in the examples of the distribution 310 and the distribution 320 are the same.

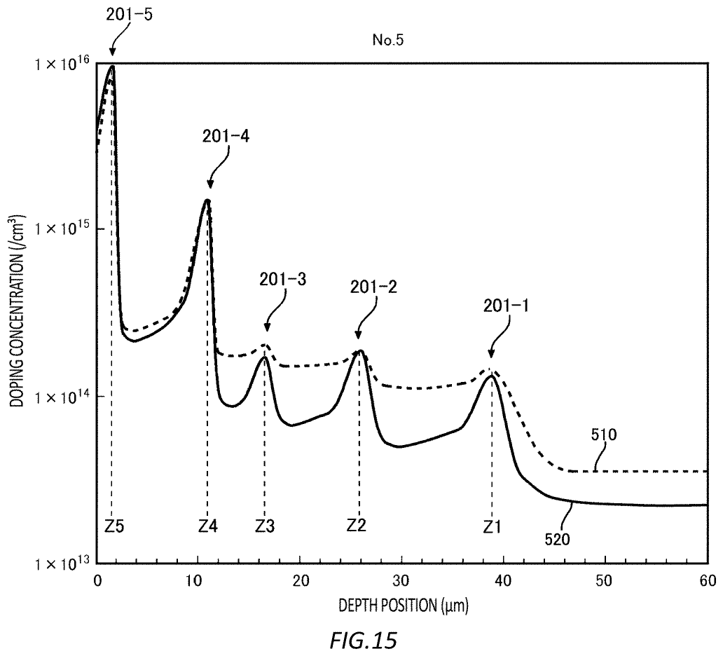

FIG. 15 is a diagram showing an example of the doping concentration distribution of the buffer region 20 according to a reference example. The buffer region 20 in the present example is formed by implanting hydrogen ions under Condition No. 5. In addition, an example in which the carbon chemical concentration of the semiconductor substrate 10 is 2.6×10¹⁵/cm³ is indicated by a distribution 510 (dotted line), and an example in which the carbon chemical concentration is 0.26×10¹⁵/cm³ is indicated by a distribution 520 (solid line). The hydrogen ion implantation conditions in the examples of the distribution 510 and the distribution 520 are the same.

In the example shown in FIG. 14, the distance (Z1−Z2) in the Z axis direction between the first doping concentration peak 201-1 and the second doping concentration peak 201-2 is smaller than that in the example shown in FIG. 15. Therefore, the CiOi-H donor ratio is relatively small. Thus, the variation Nₘₐₓ/Nₘᵢₙ can be reduced. In the example of FIG. 11, in the semiconductor device 100 of Condition No. 2, the variation Nₘₐₓ/Nₘᵢₙ is 1.3 or less regardless of the carbon chemical concentration of the semiconductor substrate 10.

In the example shown in FIG. 15, the distance (Z1−Z2) in the Z axis direction between the first doping concentration peak 201-1 and the second doping concentration peak 201-2 is relatively large. Therefore, the CiOi-H donor ratio is relatively large. Thus, it is difficult to reduce the variation Nₘₐₓ/Nₘᵢₙ. In the example of FIG. 11, in the semiconductor device 100 of Condition No. 5, the variation Nₘₐₓ/Nₘᵢₙ is larger than 1.7.

The distance (Z1−Z2) in the depth direction between the first doping concentration peak 201-1 and the second doping concentration peak 201-2 may be 5% or more and 20% or less of a distance in the depth direction of the first doping concentration peak 201-1 from the lower surface 23. The distance (Z1−Z2) may be 15% or less, or 10% or less of the distance in the depth direction of the first doping concentration peak 201-1 from the lower surface 23.

The distance (Z1−Z2) may be 1 μm or more and 20 μm or less. The distance (Z1−Z2) may be 10 μm or less, 8 μm or less, or 6 μm or less. The distance (Z1−Z2) may be 10 μm or more.

The distance in the depth direction of the first doping concentration peak 201-1 from the lower surface 23 may be 30% or more and 50% or less of a thickness in the depth direction of the semiconductor substrate 10. The distance may be 35% or more of the thickness. The distance may be 45% or less of the thickness. The distance in the depth direction of the first doping concentration peak 201-1 from the lower surface 23 may be 30 μm or more and 50 μm or less. The distance may be 35 μm or more. The distance may be 45 μm or less.

A distance in the depth direction of the second doping concentration peak 201-2 from the lower surface 23 may be 20% or more or 25% or more of the thickness in the depth direction of the semiconductor substrate 10. The distance may be 20 μm or more, or may be 25 μm or more.

The doping concentrations of the first doping concentration peak 201-1 and the second doping concentration peak 201-2 may both be 3×10¹⁴/cm³ or less. A difference in doping concentration between the first doping concentration peak 201-1 and the second doping concentration peak 201-2 may be 1×101⁴/cm³ or less.

In the above description, it has been described that the CiOi-H donor ratio in the first doping concentration peak 201-1 and the first inter-peak region 202-1 satisfies any one of Conditional Expressions 1 to 3. For example, in the buffer region 20, a depletion layer first reaches the first doping concentration peak 201-1 farthest from the lower surface 23. Therefore, when a variation in doping concentration in a vicinity of the first doping concentration peak 201-1 is large, the characteristics of the semiconductor device 100 are easily affected. In the present example, the variation Nₘₐₓ/Nₘᵢₙ in the region is reduced by adjusting the CiOi-H donor ratio in the first doping concentration peak 201-1 and the first inter-peak region 202-1. Therefore, an influence on the characteristics of the semiconductor device 100 can be suppressed. Note that also in another doping concentration peak 201-k and another inter-peak region 202-k, the CiOi-H donor ratio may satisfy any one of Conditional Expressions 1 to 3.

A distance between the doping concentration peaks 201 adjacent in the depth direction is defined as a peak-to-peak distance (Zk−Z(k+1)). From a plurality of doping concentration peaks 201, two doping concentration peaks 201 having a maximum peak-to-peak distance are extracted. In the example of FIG. 14, a distance (Z4−Z5) between a fourth doping concentration peak 201-4 and a fifth doping concentration peak 201-5 is the maximum peak-to-peak distance.

The integrated concentration of the Si—H donors at the doping concentration peak 201-k, which has a larger distance from the lower surface 23, of the two extracted doping concentration peaks 201 is denoted as N₁. In addition, the integrated concentration of the CiOi-H donors between the doping concentration peak 201-k and the doping concentration peak 201-(k+1) is denoted as N_{COH}. Also in this case, any one of Conditional Expressions 1 to 3 may be satisfied. According to the present example, even in a region where the CiOi-H donor ratio easily becomes relatively high, any one of Conditional Expressions 1 to 3 is satisfied. Therefore, it is possible to further suppress the variation in the concentration of hydrogen donors.

In another example, among the plurality of doping concentration peaks 201, a minimum doping concentration peak having a smallest doping concentration may be extracted. In the example of FIG. 14, the first doping concentration peak 201-1 is the minimum doping concentration peak. The doping concentration peak 201 adjacent to the minimum doping concentration peak on the lower surface 23 side is defined as a first adjacent doping concentration peak. In the example of FIG. 14, the second doping concentration peak 201-2 is a first adjacent doping concentration peak.

The integrated concentration of the Si—H donors at the minimum doping concentration peak is denoted as N₁, and the integrated concentration of the CiOi-H donors between the minimum doping concentration peak and the first adjacent doping concentration peak is denoted as N_{COH}. Also in this case, any one of Conditional Expressions 1 to 3 may be satisfied. According to the present example, even in the region where the CiOi-H donor ratio easily becomes relatively high, any one of Conditional Expressions 1 to 3 is satisfied. Therefore, it is possible to further suppress the variation in the concentration of hydrogen donors.

In another example, among the plurality of doping concentration peaks 201, each of the doping concentration peaks 201 from the first doping concentration peak 201-1 farthest from the lower surface 23 to a third doping concentration peak 201 second closest to the lower surface 23 (in the example of FIG. 14, a sixth doping concentration peak 201-6) is set as a target doping concentration peak. In the example of FIG. 14, the target doping concentration peak is from the first doping concentration peak 201-1 to the sixth doping concentration peak 201-6. The doping concentration peak 201 adjacent to each target doping concentration peak on the lower surface 23 side is set as a second adjacent doping concentration peak. That is, when the k-th doping concentration peak 201-k is set as the target doping concentration peak, the (k+1)-th doping concentration peak 201-(k+1) is the second adjacent doping concentration peak.

The integrated concentration of the Si—H donors at the target doping concentration peak is denoted as N₁, and the integrated concentration of the CiOi-H donors between the target doping concentration peak and the second adjacent doping concentration peak is denoted as N_{COH}. In this case, any one of Conditional Expressions 1 to 3 may be satisfied for all target doping concentration peaks. In this case, for example, the variation Nₘₐₓ/Nₘᵢₙ can be reduced over the entire buffer region 20.

While the present invention has been described by way of the embodiments, the technical scope of the present invention is not limited to the above-described embodiments. It is apparent to persons skilled in the art that various alterations or improvements can be made to the above described embodiments. It is also apparent from the described scope of the claims that the embodiments added with such alterations or improvements can be included the technical scope of the present invention.

The operations, procedures, steps, stages, or the like of each process performed by a device, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” for convenience in the claims, embodiments, or diagrams, it does not necessarily mean that the process must be performed in this order.

What is claimed is:

1. A semiconductor device comprising:
a semiconductor substrate which has an upper surface and a lower surface and contains carbon;
a plurality of hydrogen concentration peaks which are arranged side by side in a depth direction in the semiconductor substrate; and
a plurality of doping concentration peaks which are arranged corresponding to the plurality of hydrogen concentration peaks, wherein
the plurality of doping concentration peaks include a first doping concentration peak farthest from the lower surface and a second doping concentration peak second farthest from the lower surface, and
when an integrated concentration of Si—H donors at the first doping concentration peak is denoted as N₁, an integrated concentration of CiOi-H donors between the first doping concentration peak and the second doping concentration peak is denoted as N_{COH}, a carbon chemical concentration of the semiconductor substrate is denoted as N_{C}, and N=N₁+N_{COH}, a following conditional expression is satisfied:
when N_{C}≤1.5×10¹⁵/cm³,
N_{COH}/N≤0.2×N_{C}×10⁻¹⁵+0.35, and
when N_{C}>1.5×10⁻¹⁵/cm³,
N_{COH}/N≤0.65.

2. The semiconductor device according to claim 1, wherein
a following conditional expression is satisfied:
when N_{C}≤1.5×10¹⁵/cm³,
N_{COH}/N≤0.133×N_{C}×10⁻¹⁵+0.3, and
when N_{C}>1.5×10¹⁵/cm³,
N_{COH}/N≤0.5.

3. The semiconductor device according to claim 1, wherein
the plurality of doping concentration peaks include two of the doping concentration peaks adjacent to each other in the depth direction having a maximum distance therebetween, and
the conditional expression is also satisfied when an integrated concentration of Si—H donors at the doping concentration peak, which has a larger distance from the lower surface, of the two of the doping concentration peaks is denoted as N₁ and an integrated concentration of CiOi-H donors between the two of the doping concentration peaks is denoted as N_{COH}.

4. The semiconductor device according to claim 1, wherein
the plurality of doping concentration peaks include a minimum doping concentration peak having a smallest doping concentration and a first adjacent doping concentration peak adjacent to the minimum doping concentration peak on a side of the lower surface, and
the conditional expression is also satisfied when an integrated concentration of Si—H donors at the minimum doping concentration peak is denoted as N₁ and an integrated concentration of CiOi-H donors between the minimum doping concentration peak and the first adjacent doping concentration peak is denoted as N_{COH}.

5. The semiconductor device according to claim 1, wherein
when each of the doping concentration peaks, from the first doping concentration peak to a third doping concentration peak second closest to the lower surface, among the plurality of doping concentration peaks is set as a target doping concentration peak, the doping concentration peak adjacent to the target doping concentration peak on a side of the lower surface is defined as a second adjacent doping concentration peak, an integrated concentration of Si—H donors at the target doping concentration peak is denoted as N₁, and an integrated concentration of CiOi-H donors between the target doping concentration peak and the second adjacent doping concentration peak is denoted as N_{COH}, the conditional expression is satisfied for all target doping concentration peaks including the target doping concentration peak.

6. The semiconductor device according to claim 1, wherein
a distance in the depth direction of the first doping concentration peak from the lower surface is 30% or more and 50% or less of a thickness in the depth direction of the semiconductor substrate.

7. The semiconductor device according to claim 6, wherein
a distance in the depth direction between the first doping concentration peak and the second doping concentration peak is 5% or more and 20% or less of a distance in the depth direction of the first doping concentration peak from the lower surface.

8. The semiconductor device according to claim 6, wherein
a distance in the depth direction between the first doping concentration peak and the second doping concentration peak is 1 μm or more and 20 μm or less.

9. The semiconductor device according to claim 1, wherein
an oxygen chemical concentration of the semiconductor substrate is 1×10¹⁷/cm³ or more and 5×10¹⁷/cm³ or less.

10. The semiconductor device according to claim 1, wherein
a carbon chemical concentration of the semiconductor substrate is 5×10¹⁵/cm³ or less.

11. The semiconductor device according to claim 1, wherein
the semiconductor substrate has
a drift region of a first conductivity type, and
a buffer region which is provided between the drift region and the lower surface and has a higher doping concentration than that of the drift region, and
the first doping concentration peak is arranged in the buffer region.

12. A semiconductor device comprising:
a semiconductor substrate which has an upper surface and a lower surface and contains carbon;
a plurality of hydrogen concentration peaks which are arranged side by side in a depth direction in the semiconductor substrate; and
a plurality of doping concentration peaks which are arranged corresponding to the plurality of hydrogen concentration peaks, wherein
the plurality of doping concentration peaks include a first doping concentration peak farthest from the lower surface and a second doping concentration peak second farthest from the lower surface, and
when an integrated concentration of Si—H donors at the first doping concentration peak is denoted as N₁, an integrated concentration of CiOi-H donors between the first doping concentration peak and the second doping concentration peak is denoted as N_{COH}, a carbon chemical concentration of the semiconductor substrate is denoted as N_{C}, and N=N₁+N_{COH}, a following conditional expression is satisfied:
N_{COH}/N≤8.286E-02×In(N_{C})+0.4656.

13. The semiconductor device according to claim 12, wherein
a following conditional expression is satisfied:
N_{COH}/N≤7.185E-02×In(N_{C})+0.4260.

14. A semiconductor device comprising:
a semiconductor substrate which has an upper surface and a lower surface and contains carbon and oxygen;
a plurality of hydrogen concentration peaks which are arranged side by side in a depth direction in the semiconductor substrate; and
a plurality of doping concentration peaks which are arranged corresponding to the plurality of hydrogen concentration peaks, wherein
the plurality of doping concentration peaks include a first doping concentration peak farthest from the lower surface and a second doping concentration peak second farthest from the lower surface, and
when an integrated concentration of Si—H donors at the first doping concentration peak is denoted as N₁, an integrated concentration of CiOi-H donors between the first doping concentration peak and the second doping concentration peak is denoted as N_{COH}, a carbon chemical concentration of the semiconductor substrate is denoted as N_{C}, an oxygen chemical concentration of the semiconductor substrate is denoted as N_{OX}, and N=N₁+N_{COH}, a following conditional expression is satisfied:
N_{COH}/N≤8.080E-02×In(x)−2.926
where x=N_{OX}×{(N_{C}/1E15)×exp(N_{OX}/1E17)}.

15. The semiconductor device according to claim 14, wherein
a following conditional expression is satisfied:
N_{COH}/N≤6.120E-02×In(x)−2.194.

16. The semiconductor device according to claim 2, wherein
a distance in the depth direction of the first doping concentration peak from the lower surface is 30% or more and 50% or less of a thickness in the depth direction of the semiconductor substrate.

17. The semiconductor device according to claim 3, wherein
a distance in the depth direction of the first doping concentration peak from the lower surface is 30% or more and 50% or less of a thickness in the depth direction of the semiconductor substrate.

18. The semiconductor device according to claim 4, wherein
a distance in the depth direction of the first doping concentration peak from the lower surface is 30% or more and 50% or less of a thickness in the depth direction of the semiconductor substrate.

19. The semiconductor device according to claim 5, wherein
a distance in the depth direction of the first doping concentration peak from the lower surface is 30% or more and 50% or less of a thickness in the depth direction of the semiconductor substrate.

20. The semiconductor device according to claim 2, wherein
an oxygen chemical concentration of the semiconductor substrate is 1×10¹⁷/cm³ or more and 5×10¹⁷/cm³ or less.
